(19) United States
(12) Patent Application Publication
(10) Pub. No.: US 2026/0165051 A1
(43) Pub. Date: Jun. 11, 2026

(54) PROCESSING METHOD

(71) Applicant: DISCO CORPORATION, Tokyo (JP)

(72) Inventors: Akira Mizutani, Tokyo (JP); Kazuya Hirata, Tokyo (JP); Hayato Iga, Tokyo (JP); Hayato Tanaka, Tokyo (JP)

(21) Appl. No.: 19/183,285

(22) Filed: Apr. 18, 2025

(30) Foreign Application Priority Data
May 22, 2024 (JP) 2024-083410

(51) Int. Cl. H10P 34/42; B23K 26/38; H10P 52/00

(52) U.S. Cl. CPC H10P 34/42; B23K 26/38; H10P 52/00

(57) ABSTRACT

A processing method is for a wafer including a first surface and a second surface that is a rear surface of the first surface and having a chamfered portion formed on an outer periphery of the wafer. The processing method includes: irradiating an outer peripheral portion of the wafer with a laser beam to form an annular modified region inside the wafer; and forming a removed portion after the modified region is formed, the removed portion obtained by removing a part of the outer periphery of the wafer from the wafer starting from the modified region. The modified region is formed at a position where a maximum diameter of the wafer after the part is removed and a maximum diameter of the wafer before the part is removed do not differ.

### CROSS-REFERENCE TO RELATED APPLICATION(S)

The present application claims priority to and incorporates by reference the entire contents of Japanese Patent Application No. 2024-083410 filed in Japan on May 22, 2024.

### BACKGROUND

The present disclosure relates to a processing method of a wafer including a first surface and a second surface and having a chamfered portion formed on an outer periphery of the wafer.

To prevent a risk that, when a back surface of a wafer is ground and thinned, a so-called sharp edge is formed by a chamfered portion on an outer periphery of the wafer becoming an eaves shape and the wafer is damaged starting from the sharp edge, the chamfered portion is removed before grinding.

Therefore, there is proposed a method of irradiating a wafer with a laser beam to divide the wafer into an inner peripheral portion and an outer peripheral portion, removing the outer peripheral portion, and then grinding the wafer (refer to, for example, JP 2006-108532 A).

However, a diameter of the wafer is reduced after removing the outer peripheral portion.

Meanwhile, in a general chuck table that suctions and holds a wafer, a suction holding surface has the same diameter as the diameter of the wafer such as, for example, 6 inches, 8 inches, 300 mm, or the like to hold the wafer.

When the diameter of the wafer is changed to be smaller, for example, even though the chuck table tries to suction and hold the wafer in a later process, negative pressure leaks and the chuck table cannot suction and hold the wafer.

A problem also occurs when a wafer after removing the outer peripheral portion is bonded to another wafer to form a bonded wafer. In a general bonding device, since a bonding position is adjusted based on an outer peripheral position of the wafer, the bonding position may be shifted when the diameter of the wafer becomes smaller.

### SUMMARY

A processing method according to one aspect of the present disclosure is for a wafer including a first surface and a second surface that is a rear surface of the first surface and having a chamfered portion formed on an outer periphery of the wafer. The processing method includes: irradiating an outer peripheral portion of the wafer with a laser beam to form an annular modified region inside the wafer; and forming a removed portion after the modified region is formed, the removed portion obtained by removing a part of the outer periphery of the wafer from the wafer starting from the modified region. The modified region is formed at a position where a maximum diameter of the wafer after the part is removed and a maximum diameter of the wafer before the part is removed do not differ.

### BRIEF DESCRIPTION OF THE DRAWINGS

FIG. 1 is a perspective view schematically illustrating a wafer to be processed by a processing method according to a first embodiment;

FIG. 2 is a cross-sectional view taken along a line II-II in FIG. 1;

FIG. 3 is a flowchart illustrating a flow of the processing method according to the first embodiment;

FIG. 4 is a perspective view schematically illustrating a configuration example of a laser processing device that performs a modified region formation step in the processing method illustrated in FIG. 3;

FIG. 5 is a side view having a partial cross section schematically illustrating an annular floor formation step of the modified region formation step in the processing method illustrated in FIG. 3;

FIG. 6 is an enlarged cross-sectional view illustrating a portion VI in FIG. 5;

FIG. 7 is a side view having a partial cross section schematically illustrating the annular wall formation step of the modified region formation step in the processing method illustrated in FIG. 3;

FIG. 8 is an enlarged cross-sectional view illustrating a portion VIII in FIG. 7;

FIG. 9 is a cross-sectional view of a main part of the wafer after a removal step in the processing method illustrated in FIG. 3;

FIG. 10 is a cross-sectional view of a main part of a stacked wafer formed in a stacked wafer formation step in the processing method illustrated in FIG. 3;

FIG. 11 is a side view having a partial cross section schematically illustrating a grinding step in the processing method illustrated in FIG. 3;

FIG. 12 is a flowchart illustrating a flow of a processing method according to a second embodiment;

FIG. 13 is a side view having a partial cross section schematically illustrating an annular wall formation step of a modified region formation step in the processing method illustrated in FIG. 12;

FIG. 14 is an enlarged cross-sectional view illustrating a portion XIV in FIG. 13;

FIG. 15 is a side view having a partial cross section schematically illustrating the annular floor formation step of the modified region formation step in the processing method illustrated in FIG. 12;

FIG. 16 is an enlarged cross-sectional view illustrating a portion XVI in FIG. 15; and

FIG. 17 is a cross-sectional view schematically illustrating an annular floor formation step of a modified region formation step in a processing method according to a modification of the first embodiment and the second embodiment.

### DETAILED DESCRIPTION

Modes for carrying out the present disclosure (embodiments) will be described in detail with reference to the drawings. The present invention is not limited to the contents described in the following embodiments. Components described below include those that can be easily assumed by those skilled in the art and those that are substantially the same. Configurations described below can be appropriately combined. Various omissions, substitutions, or modifications in the configuration can be made without departing from the gist of the present invention.

### First Embodiment

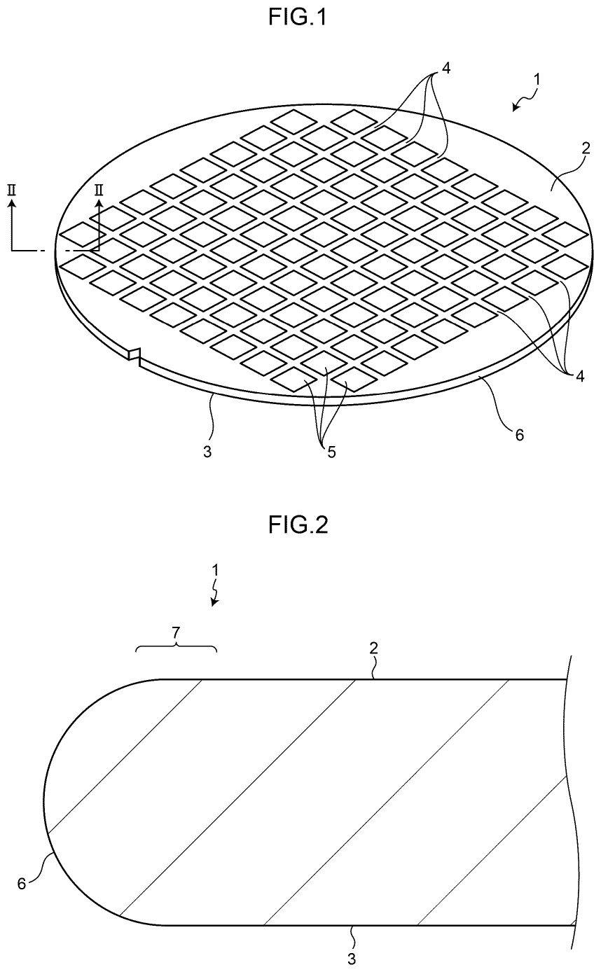

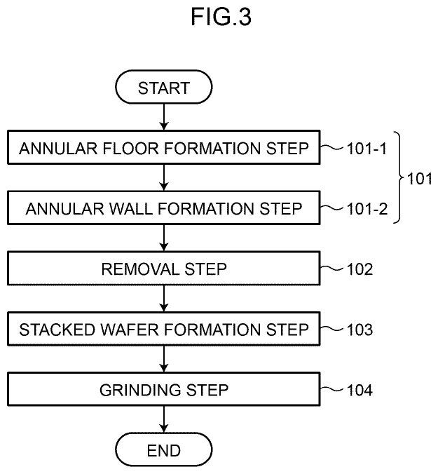

A processing method according to a first embodiment of the present disclosure will be described with reference to the drawings. FIG. 1 is a perspective view schematically illustrating a wafer to be processed by the processing method according to the first embodiment. FIG. 2 is a cross-sectional view taken along a line II-II in FIG. 1. FIG. 3 is a flowchart illustrating a flow of the processing method according to the first embodiment.

### Wafer

The processing method according to the first embodiment is a processing method of a wafer 1 illustrated in FIG. 1. In the first embodiment, the wafer 1 is a disk-shaped semiconductor wafer, an optical device wafer, or the like that uses silicon, sapphire, gallium, or the like as a substrate and that has a front surface 2 serving as a first surface and a back surface 3 serving as a second surface that is a rear surface of the front surface 2. As illustrated in FIG. 1, in the wafer 1, a plurality of lines-to-be-divided 4 that intersect each other on the front surface 2 are set, and devices 5 are formed in regions partitioned by the lines-to-be-divided 4.

Each of the devices 5 is, for example, an integrated circuit such as an integrated circuit (IC) or a large scale integration (LSI), an image sensor such as a charge coupled device (CCD) or a complementary metal oxide semiconductor (CMOS), or a memory (semiconductor storage device).

As illustrated in FIG. 2, a chamfered portion 6 is formed on an outer periphery of the wafer 1. The chamfered portion 6 is formed from the front surface 2 to the back surface 3, and is formed in an arcuate cross section so that the center in a thickness direction is located on the outermost peripheral side.

In the present disclosure, the wafer 1 may be a wafer other than a disk-shaped wafer, and the devices 5 may not be formed on the front surface 2.

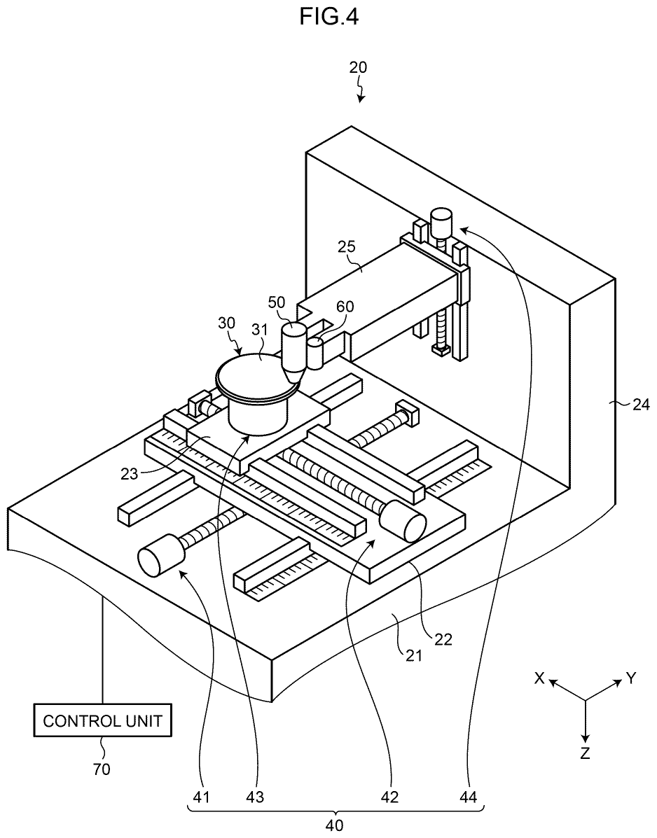

As illustrated in FIG. 3, the processing method includes a modified region formation step 101, a removal step 102, a stacked wafer formation step 103, and a grinding step 104. The modified region formation step 101 is performed by a laser processing device 20 illustrated in FIG. 4.

### Laser Processing Device

Next, the laser processing device 20 will be described. FIG. 4 is a perspective view schematically illustrating a configuration example of the laser processing device that performs the modified region formation step in the processing method illustrated in FIG. 3.

As illustrated in FIG. 4, the laser processing device 20 includes a holding table 30, a moving unit 40, a laser beam emission unit 50, an imaging unit 60, and a control unit 70.

The holding table 30 has a disk shape, and a holding surface 31 that is flat in a horizontal direction and holds the wafer 1 is formed of porous ceramic or the like. The holding table 30 is provided so that the moving unit 40 is capable of moving the holding table 30 over a processing region below the laser beam emission unit 50 and a loading/unloading region separated from below the laser beam emission unit 50 and in which the wafer 1 is loaded or unloaded.

In the holding table 30, the holding surface 31 is connected to a vacuum suction source (not illustrated) and is suctioned by the vacuum suction source so that the wafer 1 placed on the holding surface 31 is suctioned and held.

The moving unit 40 relatively moves the holding table 30 and the laser beam emission unit 50. The moving unit 40 includes a Y-axis moving unit 41 serving as an indexing feeding unit that moves the holding table 30 in a Y-axis direction parallel to the horizontal direction, an X-axis moving unit 42 serving as a processing feeding unit that moves the holding table 30 in an X-axis direction parallel to the horizontal direction and orthogonal to the Y-axis direction, a rotation moving unit 43 that rotates the holding table 30 around an axis parallel to a Z-axis direction parallel to a vertical direction, and a Z-axis moving unit 44 that moves the laser beam emission unit 50 in the Z-axis direction.

The Y-axis moving unit 41 is installed in a device body 21, and moves the holding table 30 in the Y-axis direction by moving a moving plate 22 on which the X-axis moving unit 42 is installed in the Y-axis direction. The X-axis moving unit 42 is installed on the moving plate 22, and moves the holding table 30 in the X-axis direction by moving a second moving plate 23 on which the rotation moving unit 43 is installed in the X-axis direction.

The rotation moving unit 43 is installed on the second movement plate 23, and supports the holding table 30 so that the holding table 30 is rotated around the axis. The Z-axis moving unit 44 is installed on an upright wall 24 erected from an end of the device body 21 in the Y-axis direction, and moves the laser beam emission unit 50 and the imaging unit 60 in the Z-axis direction by moving a support column 25 in the Z-axis direction, in which the laser beam emission unit 50 and the imaging unit 60 are each provided on a distal end of the support column 25.

The Y-axis moving unit 41 moves the X-axis moving unit 42, the second moving plate 23, the rotation moving unit 43, and the holding table 30 in the Y-axis direction for each moving plate 22. The X-axis moving unit 42 moves the rotation moving unit 43 and the holding table 30 in the X-axis direction for each second moving plate 23.

Each of the Y-axis moving unit 41, the X-axis moving unit 42, and the Z-axis moving unit 44 includes a known ball screw provided to be rotatable around an axis, a known motor that rotates the ball screw around an axis, and a known guide rail that supports the moving plates 22 and 23 or the support column 25 to be movable in the X-axis direction, the Y-axis direction, or the Z-axis direction. The rotation moving unit 43 includes a known motor or the like that rotates the holding table 30 around an axis.

A part of the laser beam emission unit 50 is provided at the distal end of the support column 25. The laser beam emission unit 50 irradiates the wafer 1 held on the holding table 30 with a laser beam 51 of a wavelength having transparency with respect to the wafer 1.

In the first embodiment, the laser beam emission unit 50 can freely switch between a state in which the laser beam 51 is split into a plurality of laser beams (five in the first embodiment) in the Y-axis direction and emitted onto the wafer 1 held on the holding table 30 and a state in which the laser beam 51 is not split and one laser beam 51 is emitted onto the wafer 1 held on the holding table 30. When the laser beam emission unit 50 splits the laser beam 51, the number of split laser beams is not limited as long as the laser beam 51 is split into two or more laser beams, and the laser beam is preferably split into five or more laser beams.

Note that, in the present disclosure, the laser processing device 20 may include a laser beam emission unit that splits laser beams 51 spaced apart from each other in the Y-axis direction into a plurality of laser beams and irradiates the wafer 1 held on the holding table 30 with the split laser beams, and a laser beam irradiation unit that does not split the laser beam 51 and irradiates the wafer 1 held on the holding table 30 with one laser beam 51.

The imaging unit 60 is provided at the distal end of the support column 25 and is disposed at a position aligned with the laser beam emission unit 50 in the X-axis direction. The imaging unit 60 includes an imaging element that captures an image of a region to be divided of the wafer 1 before laser processing held on the holding table 30. The imaging element is, for example, a charge coupled device (CCD) imaging element or a complementary MOS (CMOS) imaging element. The imaging unit images the wafer 1 held on the holding table 30, obtains an image used in processing such as alignment between the wafer 1 and the laser beam emission unit 50, and outputs the obtained image to the control unit 70.

The control unit 70 controls each of the components of the laser processing device 20 and causes the laser processing device 20 to perform a processing operation on the wafer 1. Note that the control unit 70 is a computer that includes an arithmetic processing device including a microprocessor such as a central processing unit (CPU), a storage device including a memory such as a read only memory (ROM) or a random access memory (RAM), and an input/output interface device. The arithmetic processing device of the control unit 70 performs arithmetic processing according to computer programs stored in the storage device, and outputs control signals for controlling the laser processing device 20 to each of the components of the laser processing device 20 via the input/output interface device.

The control unit 70 is connected to a display unit (not illustrated) configured of a liquid crystal display device or the like that displays a state, an image, or the like of the processing operation, and an input unit (not illustrated) used when an operator registers processing content information or the like. The input unit is configured of at least one of a touch panel provided on the display unit and an external input device such as a keyboard.

### Modified Region Formation Step

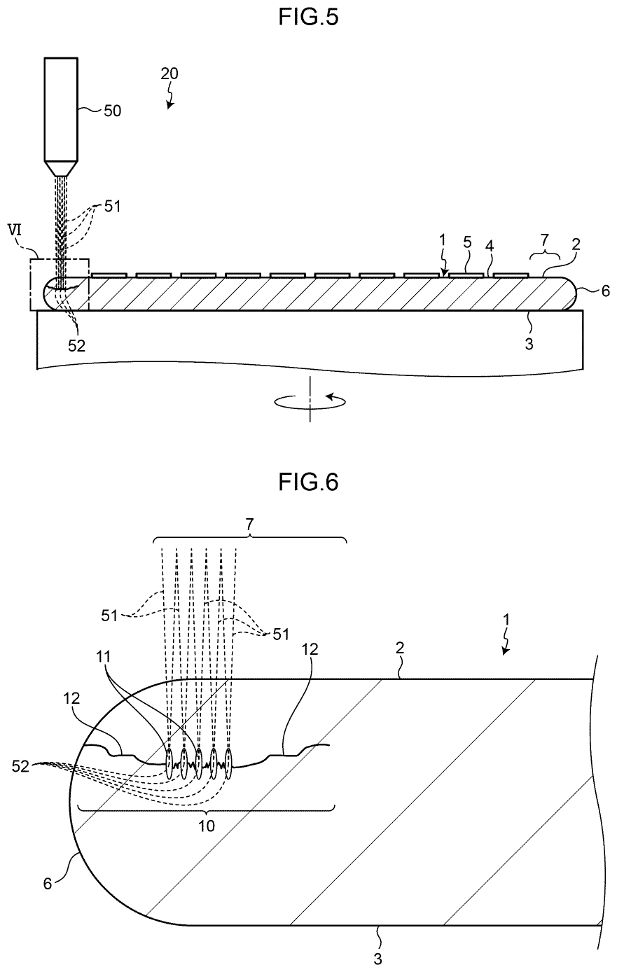

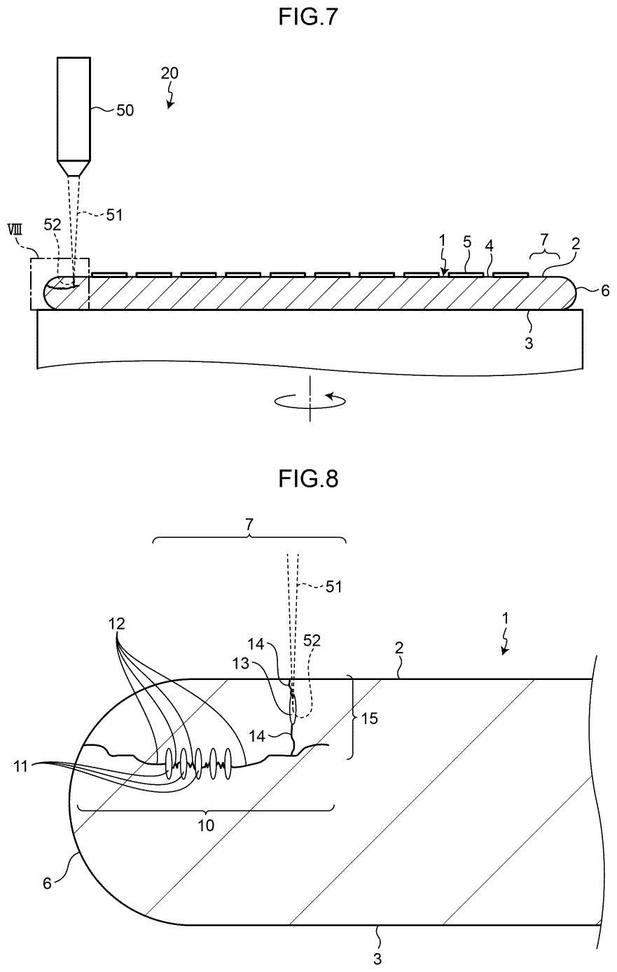

FIG. 5 is a side view having a partial cross section schematically illustrating an annular floor formation step of the modified region formation step in the processing method illustrated in FIG. 3. FIG. 6 is an enlarged cross-sectional view illustrating a portion VI in FIG. 5. FIG. 7 is a side view having a partial cross section schematically illustrating the annular wall formation step of the modified region formation step in the processing method illustrated in FIG. 3. FIG. 8 is an enlarged cross-sectional view illustrating a portion VIII in FIG. 7.

The modified region formation step 101 is a step of irradiating the chamfered portion 6 of the wafer 1 with the laser beam 51 and forming an annular floor 10 and an annular wall 15 (illustrated in FIG. 8) that are annular modified regions in the wafer 1. As illustrated in FIG. 3, the modified region formation step 101 includes an annular floor formation step 101-1 and an annular wall formation step 101-2, where the annular floor formation step 101-1 is performed and then the annular wall formation step 101-2 is performed.

In the first embodiment, in the annular floor formation step 101-1, the back surface 3 of the wafer 1 is placed on the holding surface 31 of the holding table 30 positioned in the loading/unloading region of the laser processing device 20, and the back surface 3 of the wafer 1 is suctioned and held on the holding surface 31 of the holding table 30. In the first embodiment, in the annular floor formation step 101-1, the laser processing device 20 moves the holding table 30 to the processing region by the moving unit 40, causes the imaging unit 60 to capture the wafer 1, and performs alignment.

In the first embodiment, in the annular floor formation step 101-1, as illustrated in FIG. 5, the laser processing device 20 positions a converging point 52 at a position where a distance from the front surface 2 is equal to or larger than a finished thickness of the wafer 1 after being thinned in the grinding step 104 and closer to the front surface 2 than the center of the wafer 1 in the thickness direction, and irradiates an outer peripheral portion 7 with the laser beam 51 from the front surface 2 side of the wafer 1 while rotating the holding table 30 around the axis.

Note that the outer peripheral portion 7 is a region between the chamfered portion 6 of the wafer 1 and a region in the front surface 2 on which the device 5 is formed. In the first embodiment, in the annular floor formation step 101-1, the laser beam emission unit 50 of the laser processing device 20 splits the laser beam 51 into a plurality of laser beams in the Y-axis direction, sets each converging point 52 of the split laser beams 51 at a position inside the substrate as described above, and emits the laser beams 51.

Then, since each of the laser beams 51 has a wavelength having transparency with respect to the substrate of the wafer 1, as illustrated in FIG. 6, a plurality of modified portions 11 are formed side by side in the radial direction of the wafer 1, in which a crystal structure of each of the modified portions 11 is disordered around the converging point 52 inside the substrate of the wafer 1, and a crack 12 extends from the modified portions 11 along a predetermined crystal plane of the wafer 1 in the radial direction of the wafer 1. In the first embodiment, in the annular floor formation step 101-1, the crack 12 connects the modified portions 11 to each other, the crack 12 extends from the modified portion 11 of the innermost periphery in the inner peripheral direction of the wafer 1, and the crack 12 extending from the modified portion 11 of the outermost periphery in the outer peripheral direction of the wafer 1 appears in the chamfered portion 6.

As a result, in the first embodiment, in the annular floor formation step 101-1, the annular floor 10 that is an annular region including the plurality of modified portions 11 and the crack 12 that extends from each of the plurality of modified portions 11 in the radial direction of the wafer 1 is formed inside the substrate of the wafer 1 around the entire periphery of the wafer 1. As described above, in the first embodiment, in the annular floor formation step 101-1 of the modified region formation step 101, the annular floor 10 that is an annular modified region having a predetermined width and extending from the outer peripheral edge toward the center of the wafer 1 is formed inside the substrate of the wafer 1.

In the first embodiment, in the annular wall formation step 101-2, as illustrated in FIG. 7, the laser processing device 20 positions the converging point 52 between an inner edge of the annular floor 10 and the front surface 2 of the wafer 1, and irradiates the outer peripheral portion 7 with the laser beam 51 from the front surface 2 side of the wafer 1 while rotating the holding table 30 around the axis. In the first embodiment, in the annular wall formation step 101-2, the laser beam emission unit 50 of the laser processing device 20 does not split the laser beam 51 into a plurality of laser beams in the Y-axis direction, sets the converging point 52 of one laser beam 51 at a position inside the substrate described above, and emits the laser beam 51.

Then, since the laser beam 51 has a wavelength having transparency with respect to the substrate of the wafer 1, as illustrated in FIG. 8, a modified portion 13 in which a crystal structure is disordered around the converging point 52 inside the substrate of the wafer 1 is formed, and a crack 14 extends from the modified portion 13 along a predetermined crystal plane of the wafer 1 in the thickness direction of the wafer 1. In the first embodiment, in the annular wall formation step 101-2, the crack 14 extending toward the back surface 3 of the wafer 1 is connected to an inner edge of the crack 12 of the annular floor 10, and the crack 14 extending toward the front surface 2 of the wafer 1 appears on the front surface 2 of the wafer 1.

As a result, in the first embodiment, in the annular wall formation step 101-2, the annular wall 15 that is an annular region including the modified portion 13 and the crack 14 that extends from the modified portion 13 in the thickness direction of the wafer 1 is formed inside the substrate of the wafer 1 around the entire periphery of the wafer 1. In the first embodiment, in the annular wall formation step 101-2 of the modified region formation step 101, the annular wall 15 that is an annular modified region having a predetermined depth and extending from the front surface 2 side toward the back surface 3 side is formed inside the substrate of the wafer 1.

Thus, in the first embodiment, in the modified region formation step 101, the laser beam 51 is emitted toward the front surface 2 side of the wafer 1, the annular floor 10 is formed, and then the annular wall 15 is formed. In the first embodiment, in the modified region formation step 101, by setting the converging point 52 at the position described above, the annular floor 10 and the annular wall 15 that are modified regions are formed at positions where the maximum diameter of the wafer 1 after being partially removed in the removal step 102 and the maximum diameter of the wafer 1 before the removal step 102 is performed do not differ (that is, positions where the maximum diameter does not change).

### Removal Step

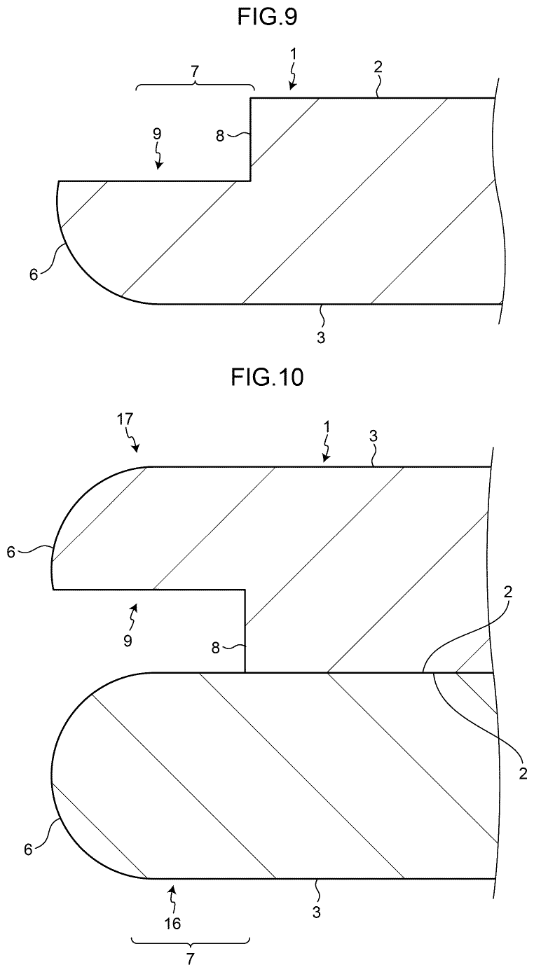

FIG. 9 is a cross-sectional view of a main part of the wafer after the removal step of the processing method illustrated in FIG. 3. The removal step 102 is a step of forming a removed portion 9 after performing the modified region formation step 101, the removed portion 9 obtained by removing a part of the outer peripheral portion 7 and the chamfered portion 6 of the wafer 1 from the wafer 1 starting from the annular floor 10 and the annular wall 15.

In the first embodiment, in the removal step 102, for example, ultrasonic vibration is applied to the chamfered portion 6 of the wafer 1 via liquid such as pure water to break the substrate of the wafer 1 starting from the annular floor 10 and the annular wall 15, and as illustrated in FIG. 9, a part of the outer peripheral portion 7 and the chamfered portion 6 between the annular floor 10 and the front surface 2 and on the outer periphery side of the annular wall 15 is removed to form the removed portion 9 on the wafer 1. Note that the removed portion 9 is formed in a stepped shape at an outer edge of the wafer 1 by removing the front surface 2 side from the center of the outer periphery in the thickness direction of the region of the wafer 1 where the device 5 is formed, and includes an annular wall 8 along a direction orthogonal to the front surface 2 and the back surface 3.

In the present disclosure, in the removal step 102, a part of the outer peripheral portion 7 and the chamfered portion 6 between the annular floor 10 and the front surface 2 of the wafer 1 and on the outer peripheral side of the annular wall 15 may be removed from the wafer 1 starting from the annular floor 10 and the annular wall 15 by air blowing, jetting of a high-pressure fluid, or the like.

### Stacked Wafer Formation Step

FIG. 10 is a cross-sectional view of a main part of a stacked wafer formed in the stacked wafer formation step in the processing method illustrated in FIG. 3. The stacked wafer formation step 103 is a step of forming a stacked wafer 17 after the removal step 102 is performed, the stacked wafer 17 obtained by stacking the wafer 1 on a second wafer 16 while the front surface 2 side of the wafer 1 faces the second wafer 16.

In the first embodiment, in the stacked wafer formation step 103, the second wafer 16 having the same configuration as that of the wafer 1 is prepared. Note that the same portions of the second wafer 16 as those of the wafer 1 will be denoted by the same reference numerals for description. In the first embodiment, in the stacked wafer formation step 103, the front surfaces 2 of the wafers 1 and 16 are made to face each other, and the wafers 1 and 16 are positioned at positions where the outer edges of the wafers 1 and 16 overlap each other with reference to the outer edges.

In the first embodiment, in the stacked wafer formation step 103, the front surfaces 2 of the wafers 1 and 16 are bonded to each other to form the stacked wafer 17 in which the wafers 1 and 16 are stacked, as illustrated in FIG. 10. Note that, when bonding the wafers 1 and 16 to each other, the wafers are bonded to each other by fusion bonding, direct bonding, bonding using a temporary adhesive, or the like, and a bonding method is not limited. In the first embodiment, the second wafer 16 has the same configuration as that of the wafer 1, but may have a different configuration as long as the outer diameter is the same as that of the wafer 1.

### Grinding Step

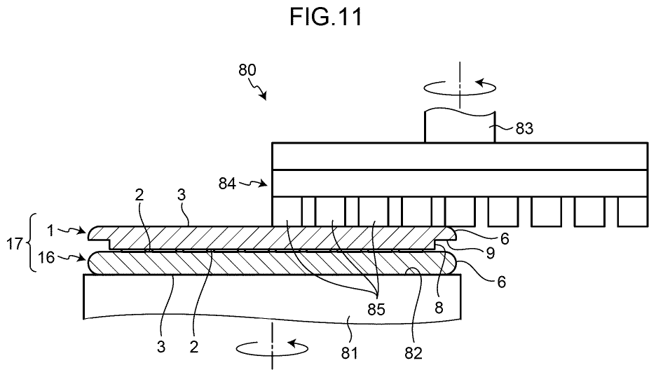

FIG. 11 is a side view having a partial cross section schematically illustrating the grinding step in the processing method illustrated in FIG. 3. The grinding step 104 is a step of grinding the back surface 3 of the wafer 1 of the stacked wafer 17 after performing the stacked wafer formation step 103 and grinding the wafer 1 to a finished thickness reaching the removed portion 9.

In the first embodiment, in the grinding step 104, a grinding device 80 illustrated in FIG. 11 suctions and holds the back surface 3 of the second wafer 16 of the stacked wafer 17 on a holding surface 82 of a holding table 81. In the first embodiment, in the grinding step 104, as illustrated in FIG. 11, the grinding device 80 supplies grinding water while rotating a grinding wheel 84 around an axis by a spindle 83 and rotating the holding table 81 around an axis, and a grinding whetstone 85 is brought into contact with the back surface 3 of the wafer 1 of the stacked wafer 17 and is brought close to the holding table 81 at a predetermined feeding speed so that the back surface 3 of the wafer 1 of the stacked wafer 17 is grinded by the grinding whetstone 85.

In the first embodiment, in the grinding step 104, the grinding device 80 grinds the back surface 3 of the wafer 1 of the stacked wafer 17 until the wafer 1 of the stacked wafer 17 has a predetermined finished thickness.

In the processing method according to the first embodiment described above, in the modified region formation step 101, the annular floor 10 and the annular wall 15 that are modified regions are formed at positions where the maximum diameter of the wafer 1 does not change before and after the removal step 102, and then, in the removal step 102, a part of the outer peripheral portion 7 and the chamfered portion 6 of the wafer 1 is removed from the wafer 1 starting from the annular floor 10 and the annular wall 15.

As a result, the processing method according to the first embodiment has an effect of being able to prevent the diameter of the wafer 1 from being reduced even when the outer peripheral portion is removed before the grinding step 104.

In the processing method according to the first embodiment, a sharp edge may be formed while the wafer 1 is ground and thinned if the annular floor 10 is inclined, but by forming the annular wall 15 so that the annular wall 8 is formed on the outer peripheral portion 7 of the wafer 1 after the removal step 102, no sharp edge is formed when the wafer 1 is ground and thinned.

In the processing method according to the first embodiment, cracking may occur during grinding if the annular wall 15 extends to the back surface 3 side from the annular floor 10, but when the annular floor 10 is formed in advance by emitting the laser beam 51 toward the front surface 2 side, it is possible to prevent the crack 14 generated when the annular wall 15 is formed from extending to the back surface 3 side of the wafer 1 from a lower end of the annular floor 10.

In the processing method according to the first embodiment, since the stacked wafer 17 is formed after the removal step 102, it is possible to prevent the second wafer 16 from being damaged.

### Second Embodiment

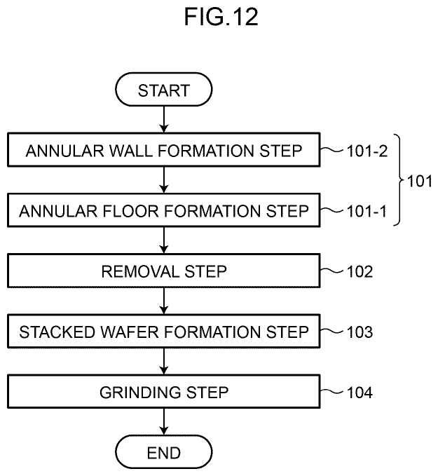

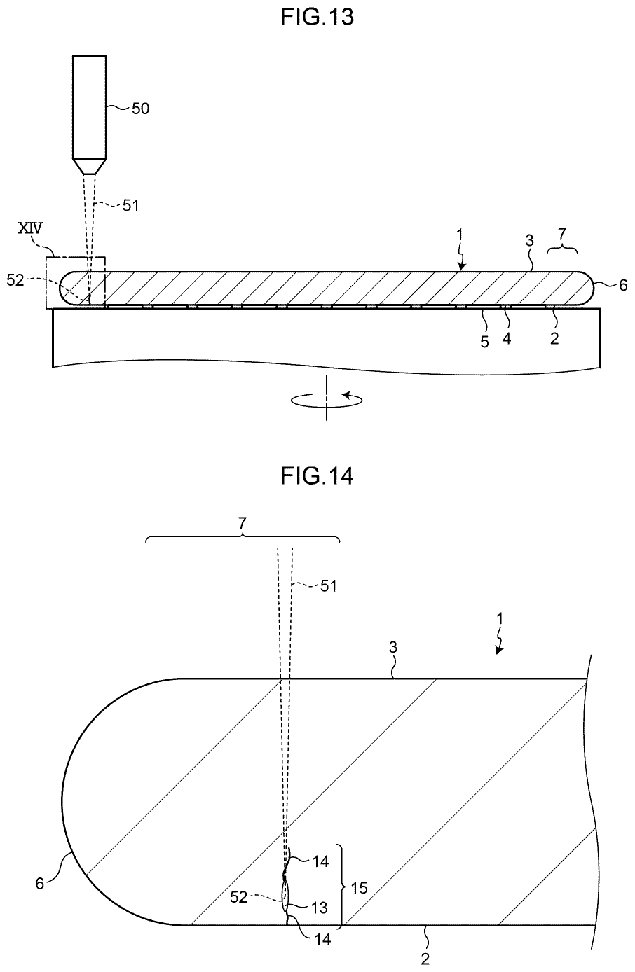

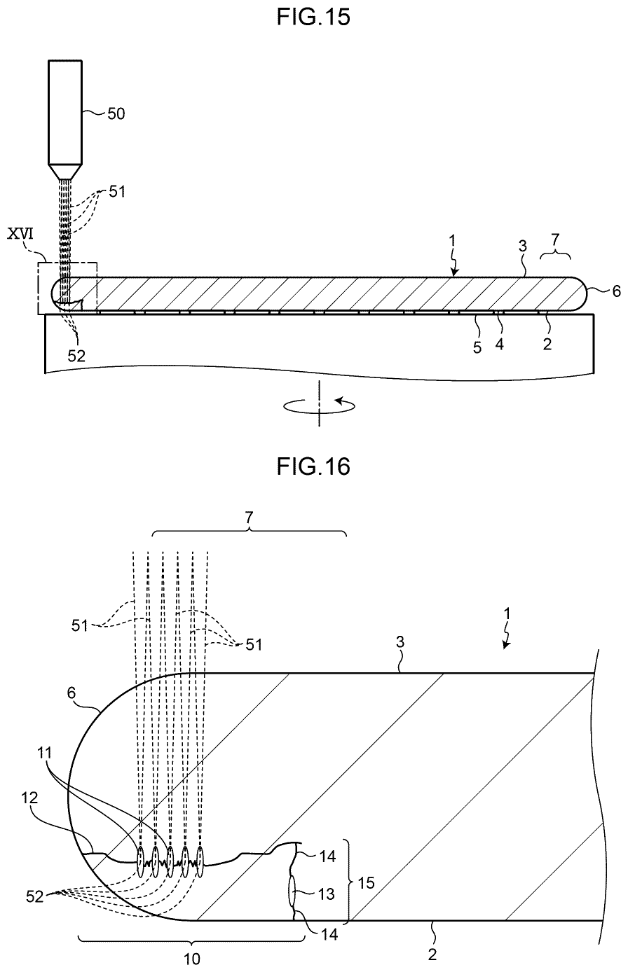

A processing method according to a second embodiment will be described with reference to the drawings. FIG. 12 is a flowchart illustrating a flow of the processing method according to the second embodiment. FIG. 13 is a side view having a partial cross section schematically illustrating an annular wall formation step of a modified region formation step in the processing method illustrated in FIG. 12. FIG. 14 is an enlarged cross-sectional view illustrating a portion XIV in FIG. 13. FIG. 15 is a side view having a partial cross section schematically illustrating the annular floor formation step of the modified region formation step in the processing method illustrated in FIG. 12. FIG. 16 is an enlarged cross-sectional view illustrating a portion XVI in FIG. 15. Note that, in FIGS. 12, 13, 14, 15, and 16, the same portions as those of the first embodiment will be denoted by the same reference numerals, and descriptions thereof will be omitted.

In the second embodiment, as illustrated in FIG. 12, the modified region formation step 101 is the same as that of the first embodiment except that the modified region formation step 101 includes the annular wall formation step 101-2 and the annular floor formation step 101-1, where the annular wall formation step 101-2 is performed and then the annular floor formation step 101-1 is performed.

In the second embodiment, in the annular wall formation step 101-2, the laser processing device 20 is placed on the holding surface 31 of the holding table 30 in which the front surface 2 of the wafer 1 is positioned in the loading/unloading region, and the front surface 2 of the wafer 1 is suctioned and held on the holding surface 31 of the holding table 30. In the second embodiment, in the annular wall formation step 101-2, the laser processing device 20 moves the holding table 30 to the processing region by the moving unit 40, causes the imaging unit 60 that is an infrared camera to capture the wafer 1, and performs alignment.

In the second embodiment, in the annular wall formation step 101-2, as illustrated in FIG. 13, the laser processing device 20 positions the converging point 52 closer to the front surface 2 than the center of the wafer 1 in the thickness direction, and irradiates the outer peripheral portion 7 with the laser beam 51 from the back surface 3 side of the wafer 1 while rotating the holding table 30 around the axis. In the second embodiment, in the annular wall formation step 101-2, the laser beam emission unit 50 of the laser processing device 20 does not split the laser beam 51 into a plurality of laser beams in the Y-axis direction, sets the converging point 52 of one laser beam 51 at a position inside the substrate described above, and emits the laser beam 51.

Then, since the laser beam 51 has a wavelength having transparency with respect to the substrate of the wafer 1, as illustrated in FIG. 14, the modified portion 13 in which a crystal structure is disordered around the converging point 52 inside the substrate of the wafer 1 is formed, and the crack 14 extends from the modified portion 13 along a predetermined crystal plane of the wafer 1 in the thickness direction of the wafer 1. In the second embodiment, in the annular wall formation step 101-2, the crack 14 extends toward the back surface 3 of the wafer 1, and the crack 14 extended toward the front surface 2 of the wafer 1 appears on the front surface 2 of the wafer 1.

As a result, in the second embodiment, in the annular wall formation step 101-2, the annular wall 15 including the modified portion 13 and the crack 14 that extends from the modified portion 13 in the thickness direction of the wafer 1 is formed inside the substrate of the wafer 1 around the entire periphery of the wafer 1. As described above, in the second embodiment, in the annular wall formation step 101-2 of the modified region formation step 101, the annular wall 15 that is an annular modified region having a predetermined depth and extending from the front surface 2 side toward the back surface 3 side is formed inside the substrate of the wafer 1.

In the second embodiment, in the annular floor formation step 101-1, as illustrated in FIG. 15, the laser processing device 20 positions the converging point 52 at a position that has a distance from the front surface 2 equal to or larger than a finished thickness of the wafer 1 after being thinned in the grinding step 104, is on the outer peripheral side of the annular wall 15, and is closer to the front surface 2 than the center of the wafer 1 in the thickness direction, and irradiates the outer peripheral portion 7 with the laser beam 51 from the back surface 3 side of the wafer 1 while rotating the holding table 30 around the axis. In the second embodiment, in the annular floor formation step 101-1, the laser beam emission unit 50 of the laser processing device 20 splits the laser beam 51 into a plurality of laser beams in the Y-axis direction, sets each converging point 52 of the split laser beams 51 at the position inside the substrate as described above, and emits the laser beams 51.

Then, since each of the laser beams 51 has a wavelength having transparency with respect to the substrate of the wafer 1, as illustrated in FIG. 16, the plurality of modified portions 11 are formed side by side in the radial direction of the wafer 1, in which a crystal structure of each of the modified portions 11 is disordered around the converging point 52 inside the substrate of the wafer 1, and the crack 12 extends from the modified portions 11 along the predetermined crystal plane of the wafer 1 in the radial direction of the wafer 1. In the second embodiment, in the annular floor formation step 101-1, the crack 12 connects the modified portions 11 to each other, the crack 12 extended from the modified portion 11 of the innermost periphery in the inner peripheral direction of the wafer 1 is connected to the crack 14 extended on the back surface 3 side of the annular wall 15, and the crack 12 extended in the outer peripheral direction of the wafer 1 from the modified portion 11 of the outermost periphery appears on the front surface of the chamfered portion 6.

As a result, in the second embodiment, in the annular floor formation step 101-1, the annular floor 10 including the plurality of modified portions 11 and the crack 12 that extends from the plurality of modified portions 11 in the radial direction of the wafer 1 is formed inside the substrate of the wafer 1 around the entire periphery of the wafer 1. As described above, in the second embodiment, in the annular floor formation step 101-1 of the modified region formation step 101, the annular floor 10 that is an annular modified region having a predetermined width and extending from the outer peripheral edge toward the center of the wafer 1 is formed inside the substrate of the wafer 1.

Thus, in the second embodiment, in the modified region formation step 101, the laser beam 51 is emitted toward the back surface 3 side of the wafer 1, the annular wall 15 is formed, and then the annular floor 10 is formed. In the second embodiment, in the modified region formation step 101, by setting the converging point 52 at the position described above, the annular floor 10 and the annular wall 15 are formed at positions where the maximum diameter of the wafer 1 after being partially removed in the removal step 102 and the maximum diameter of the wafer 1 before the removal step 102 is performed do not differ (that is, positions where the maximum diameter does not change).

In the processing method according to the second embodiment, in the modified region formation step 101, the annular floor 10 and the annular wall 15 that are modified regions are formed at positions where the maximum diameter of the wafer 1 does not change before and after the removal step 102, and then, in the removal step 102, a part of the outer peripheral portion 7 and the chamfered portion 6 of the wafer 1 is removed from the wafer 1 starting from the annular floor 10 and the annular wall 15, so that it is possible to obtain an effect of preventing the diameter of the wafer 1 from being reduced even when the outer peripheral portion is removed before the grinding step 104 as in the first embodiment.

In the processing method according to the second embodiment, usually, the crack 14 hardly extends to the front surface 2 on which the device 5 is formed, but since the laser beam 51 is first emitted toward the back surface 3, the crack 14 easily extends to the front surface 2 so that a device layer configuring the device 5 is easily removed by the crack 14 when the wafer 1 is a device wafer on which the device 5 is formed.

When the laser beam 51 is first emitted toward the back surface 3 side of the wafer 1, it is difficult to form the annular wall 15 after forming the annular floor 10, but since the processing method according to the second embodiment performs the annular wall formation step 101-2 and then performs the annular floor formation step 101-1, the annular floor 10 and the annular wall 15 that are modified regions can be formed inside the wafer 1.

### Modification

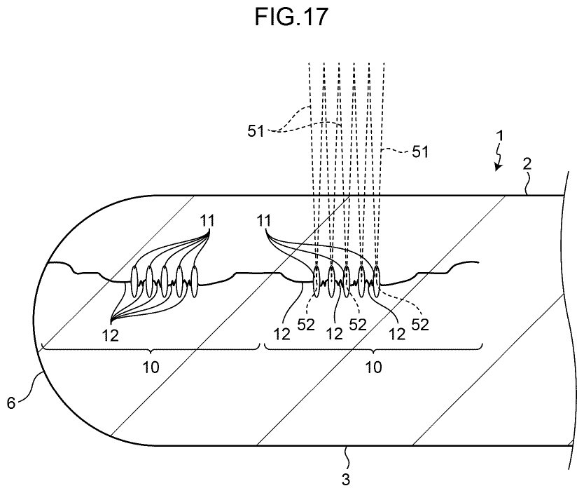

A processing method according to a modification of the first embodiment and the second embodiment will be described with reference to the drawings. FIG. 17 is a cross-sectional view schematically illustrating an annular floor formation step of a modified region formation step in the processing method according to the modification of the first embodiment and the second embodiment. Note that, in FIG. 17, the same portions as those of the first embodiment will be denoted by the same reference numerals, and descriptions thereof will be omitted.

The annular floor formation step 101-1 of the modified region formation step 101 of the processing method according to the modification is the same as that of the first embodiment except that the laser processing device 20 sequentially forms a plurality of annular floors 10 from the outer peripheral edge toward the center side of the wafer 1 as illustrated in FIG. 17. Note that FIG. 17 illustrates an example in which the laser beam 51 is first emitted toward the front surface 2 side of the wafer 1, but in the present disclosure, the laser beam 51 may be first emitted toward the back surface 3 side of the wafer 1. In the present disclosure, when the laser beam 51 is first emitted toward the back surface 3 side of the wafer 1, it is desirable to sequentially form a plurality of annular floors 10 from the outer peripheral edge toward the center side after the annular wall 15 is formed.

In the processing method according to the modification, in the modified region formation step 101, the annular floor 10 and the annular wall 15 that are modified regions are formed at positions where the maximum diameter of the wafer 1 does not change before and after the removal step 102, and then, in the removal step 102, a part of the outer peripheral portion 7 and the chamfered portion 6 of the wafer 1 is removed from the wafer 1 starting from the annular floor 10 and the annular wall 15, so that it is possible to obtain an effect of preventing the diameter of the wafer 1 from being reduced even when the outer peripheral portion is removed before the grinding step 104 as in the first embodiment.

In the processing method according to the modification, since the annular floor 10 formed on the outer peripheral edge of the wafer 1 is opened by forming the annular floor 10 from the outer peripheral edge toward the center side, the crack 12 by the laser beam 51 emitted later is likely to extend to the outer periphery of the wafer 1.

According to the present disclosure, it is possible to prevent a diameter of a wafer from being reduced even when an outer peripheral portion of the wafer is removed before grinding.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A processing method for a wafer including a first surface and a second surface that is a rear surface of the first surface and having a chamfered portion formed on an outer periphery of the wafer, the processing method comprising:
irradiating an outer peripheral portion of the wafer with a laser beam to form an annular modified region inside the wafer; and
forming a removed portion after the modified region is formed, the removed portion obtained by removing a part of the outer periphery of the wafer from the wafer starting from the modified region, wherein
the modified region is formed at a position where a maximum diameter of the wafer after the part is removed and a maximum diameter of the wafer before the part is removed do not differ.

2. The processing method according to claim 1, wherein the forming of the modified region includes forming inside the wafer an annular floor including an annular modified region having a predetermined width from an outer peripheral edge toward a center of the wafer, and forming inside the wafer an annular wall including an annular modified region having a predetermined depth from the first surface side toward the second surface side.

3. The processing method according to claim 2, wherein the forming of the modified region includes emitting a laser beam toward the first surface side of the wafer to form the annular floor, and then forming the annular wall.

4. The processing method according to claim 2, wherein the forming of the modified region includes emitting a laser beam from the second surface side of the wafer to form the annular wall, and then forming the annular floor.

5. The processing method according to claim 2, wherein the forming of the modified region includes sequentially forming a plurality of annular floors from the outer peripheral edge toward the center of the wafer.

6. The processing method according to claim 1, further comprising:
forming a stacked wafer after the part is removed, the stacked wafer obtained by stacking the wafer on a second wafer while the first surface side of the wafer faces the second wafer.

7. The processing method according to claim 6, further comprising:
grinding the second surface of the stacked wafer after the stacked wafer is formed, and grinding the stacked wafer to a thickness reaching the removed portion.
